(19) United States
(12) Patent Application Publication
(10) Pub. No.: US 2025/0266509 A1
(43) Pub. Date: Aug. 21, 2025

(54) HYBRID WIRELESS COMMUNICATION FOR BATTERY MONITORING AND MANAGEMENT SYSTEMS

(71) Applicant: Caterpillar Inc., Peoria, IL (US)

(72) Inventors: Jeffrey ABNEY, Morton, IL (US); Wellington Y. KWOK, Dunlap, IL (US); Michael J. KILKENNY, Peoria, IL (US)

(73) Assignee: Caterpillar Inc., Peoria, IL (US)

(21) Appl. No.: 18/442,356

(22) Filed: Feb. 15, 2024

(51) Int. Cl. H01M 10/42; G01R 31/371; H01M 50/204

(52) U.S. Cl. CPC H01M 10/425; G01R 31/371; H01M 50/204; H01M 2010/4271

(57) ABSTRACT

In some implementations, a first wireless receiver of a battery module of a battery pack may receive, using a first wireless communication technology, data from a first wireless transmitter of a chip-on-cell device connected to a battery cell of the battery module. The data may indicate one or more properties of the battery cell detected by the chip-on-cell device. The first wireless receiver may transfer the data to a second wireless transmitter of the battery module. The second wireless transmitter may transmit, using a second wireless communication technology, the data to a second wireless receiver of a battery management system (BMS) of the battery pack.

### TECHNICAL FIELD

The present disclosure relates generally to batteries and, for example, to hybrid wireless communication for battery monitoring and management systems.

### BACKGROUND

A machine may include one or more battery packs to provide power to components of the machine, such as lights, computer systems, and/or a motor, among other examples. A battery pack may be associated with a modular design that includes multiple battery modules. A battery module may include multiple battery cells. The battery pack may include a battery monitoring or management system (BMS) which can be referred to interchangeably as a “battery monitoring system” or a “battery management system.” The BMS may be a wired BMS, meaning that various sensors for the battery cells connect to battery module controllers by wire harnesses, and/or that the battery module controllers connect to a main BMS controller of the BMS by wire harnesses. These numerous wire harnesses increase a cost and complexity of the BMS. Moreover, the wire harnesses are susceptible to electrical defects, wire abrasion, improper installation, and/or disconnection (e.g., due to vibration), among other examples, and therefore are associated with poor reliability.

Korea Patent Application Publication No. KR20230082110A (the '110 publication) discloses a battery authentication system. The '110 publication indicates that when a battery is installed, a vehicle controller may determine whether the battery is permissible. The vehicle controller may include a communication module to enable short-range wireless communication with a user terminal, and a communication module to enable long-distance wireless communication with a security server. The short-range and long-distance wireless communications of the '110 publication are not used to facilitate wireless communication between devices within a battery pack.

The communication system of the present disclosure solves one or more of the problems set forth above and/or other problems in the art.

### SUMMARY

A method may include receiving, by a first wireless receiver of a battery module of a battery pack and using a first wireless communication technology, data from a first wireless transmitter of a chip-on-cell device connected to a battery cell of the battery module. The data may indicate one or more properties of the battery cell detected by the chip-on-cell device. The method may include transferring, by the first wireless receiver, the data to a second wireless transmitter of the battery module. The method may include transmitting, by the second wireless transmitter and using a second wireless communication technology, the data to a second wireless receiver of a BMS of the battery pack.

A battery pack may include a battery module. The battery module may include a plurality of battery cells. The battery module may include a plurality of chip-on-cell devices connected to respective battery cells of the plurality of battery cells. The battery module may include a first wireless receiver configured to receive data from a first wireless transmitter of a chip-on-cell device, of the plurality of chip-on-cell devices, using a first wireless communication technology. The battery module may include a second wireless transmitter configured to obtain the data from the first wireless receiver via a wired connection. The battery module may include BMS including a second wireless receiver configured to receive the data from the second wireless transmitter using a second wireless communication technology.

A communication system for a battery module may include a plurality of chip-on-cell devices connected to respective battery cells of the battery module. The communication system may include a first wireless receiver configured to receive data from a first wireless transmitter of a chip-on-cell device, of the plurality of chip-on-cell devices, using a first wireless communication technology. The communication system may include a second wireless transmitter configured to transmit the data to a second wireless receiver using a second wireless communication technology.

### BRIEF DESCRIPTION OF THE DRAWINGS

FIG. 1 is a diagram of an example battery pack.

FIG. 2 is a diagram of an example battery module.

FIG. 3 is a diagram of an example communication system.

FIG. 4 is a flowchart of an example process associated with hybrid wireless communication for a BMS.

### DETAILED DESCRIPTION

This disclosure relates to a communication system, which is applicable to any battery pack that employs a BMS. For example, such battery packs may be used in electric vehicles, or the like. As used herein, “battery cell,” “battery,” and “cell” may be used interchangeably.

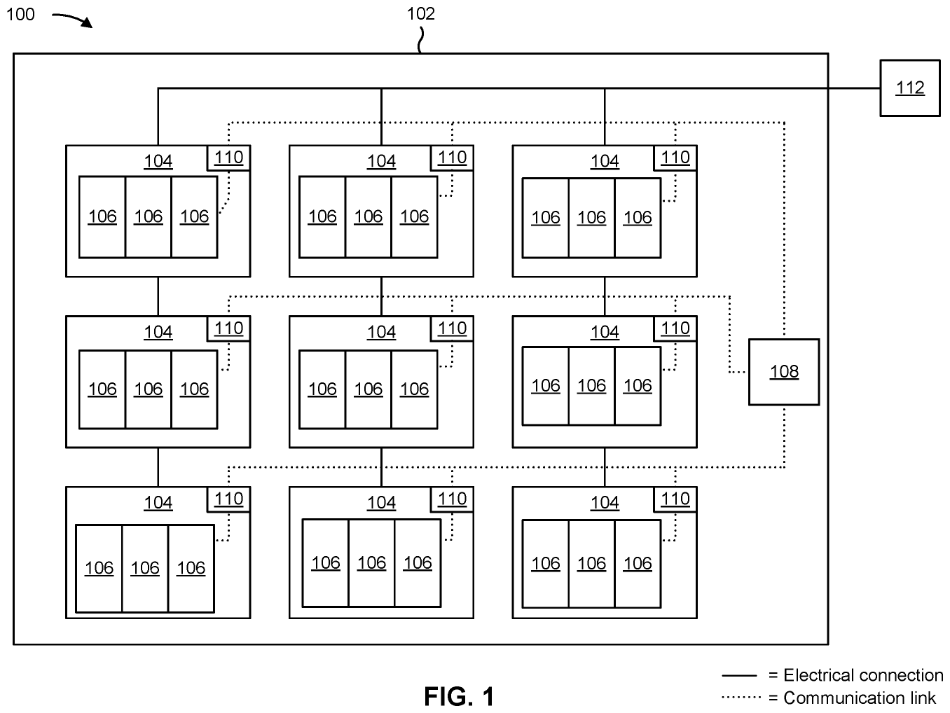

FIG. 1 is a diagram of an example battery pack 100. The battery pack 100 may include a battery pack housing 102, one or more battery modules 104, and one or more battery cells 106. The battery pack 100 includes a battery pack controller 108 associated with storing information and/or controlling one or more operations associated with the battery pack 100. Each battery module 104 includes a module controller 110 associated with storing information and/or controlling one or more operations associated with the battery module 104.

The battery pack 100 may be associated with a component 112. The component 112 may be powered by the battery pack 100. For example, the component 112 can be a load that consumes energy provided by the battery pack 100, such as electronics or an electric motor, among other examples. As another example, the component 112 provides energy to the battery pack 100 (e.g., to be stored by the battery cells 106). In such examples, the component 112 may be a power generator, a solar energy system, and/or a wind energy system, among other examples.

The battery pack housing 102 may include metal shielding (e.g., steel, aluminum, or the like) to protect elements (e.g., battery modules 104, battery cells 106, the battery pack controller 108, the module controllers 110, wires, circuit boards, or the like) positioned within battery pack housing 102. Each battery module 104 includes one or more (e.g., a plurality of) battery cells 106 (e.g., positioned within a housing of the battery module 104). Battery cells 106 may be connected in series and/or in parallel within the battery module 104 (e.g., via terminal-to-busbar welds). Each battery cell 106 is associated with a chemistry type. The chemistry type may include lithium ion (Li-ion) (e.g., lithium ion polymer (Li-ion polymer), lithium iron phosphate (LFP), and/or nickel manganese cobalt (NMC)), nickel-metal hydride (NiMH), or nickel cadmium (NiCd), among other examples.

The battery modules 104 may be arranged within the battery pack 100 in one or more strings. For example, the battery modules 104 are connected via electrical connections, as shown in FIG. 1. The electrical connections may be removable, such as via bolts and/or nuts at one or more terminals on housings of the battery modules 104. The battery modules 104 may be connected in series and/or in parallel. For example, a number of battery modules 104 may be connected in series to provide a particular voltage (e.g., to the component 112). Alternatively, a number of battery modules 104 may be connected in parallel to increase a current and/or a power output of the battery pack 100. The number of battery cells 106 included in each battery module 104, and the number of battery modules 104 included in the battery pack 100 (e.g., and the relative serial and/or parallel connections of the battery cells 106 and/or the battery modules 104) may be associated with the required output power and an intended use of the battery pack 100. For example, any number of battery cells 106 can be included in a battery module 104. Similarly, any number of battery modules 104 can be included in the battery pack 100.

The battery pack controller 108 is communicatively connected (e.g., via a communication link) to each module controller 110. The battery pack controller 108 may be associated with receiving, generating, storing, processing, providing, and/or routing information associated with the battery pack 100. The battery pack controller 108 may also be referred to as a battery pack management device or system. The battery pack controller 108 may communicate with the component 112 and/or a controller of the component 112, may control a start-up and/or shut-down procedure of the battery pack 100, may monitor a current and/or voltage of a string (e.g., of battery modules 104), and/or may monitor and/or control a current and/or voltage provided by the battery pack 100, among other examples. A module controller 110 may be associated with receiving, generating, storing, processing, providing, and/or routing information associated with a battery module 104. The module controller 110 may communicate with the battery pack controller 108.

The battery pack controller 108 and/or a module controller 110 may be associated with monitoring and/or determining a state of charge (SOC), a state of health (SOH), a depth of discharge (DOD), an output voltage, a temperature, and/or an internal resistance and impedance, among other examples, associated with a battery module 104 and/or associated with the battery pack 100. Additionally, or alternatively, the battery pack controller 108 and/or the module controller 110 may be associated with monitoring, controlling, and/or reporting one or more parameters associated with battery cells 106. The one or more parameters may include cell voltages, temperatures, chemistry types, a cell energy throughput, a cell internal resistance, and/or a quantity of charge-discharge cycles, among other examples.

The battery pack controller 108 and/or a module controller 110 includes one or more processors and/or one or more memories. A processor may include a central processing unit, a microprocessor, a controller, a microcontroller, a digital signal processor, a field-programmable gate array, an application-specific integrated circuit, and/or another type of processing component. The processor may be implemented in hardware, firmware, or a combination of hardware and software. In some implementations, the processor may include one or more processors capable of being programmed to perform one or more operations or processes described elsewhere herein. A memory may include volatile and/or nonvolatile memory. For example, the memory may include random access memory (RAM), read only memory (ROM), and/or another type of memory (e.g., a flash memory, a magnetic memory, and/or an optical memory). The memory may include internal memory (e.g., RAM, ROM, or a hard disk drive) and/or removable memory (e.g., removable via a universal serial bus connection). The memory may be a non-transitory computer-readable medium. The memory may store information, one or more instructions, and/or software (e.g., one or more software applications) related to the operation of the battery pack 100, a battery module 104, and/or a battery cell 106. The memory may include one or more memories that are coupled (e.g., communicatively coupled) to the processor, such as via a bus. Communicative coupling between a processor and a memory may enable the processor to read and/or process information stored in the memory and/or to store information in the memory.

As indicated above, FIG. 1 is provided as an example. Other examples may differ from what is described with regard to FIG. 1.

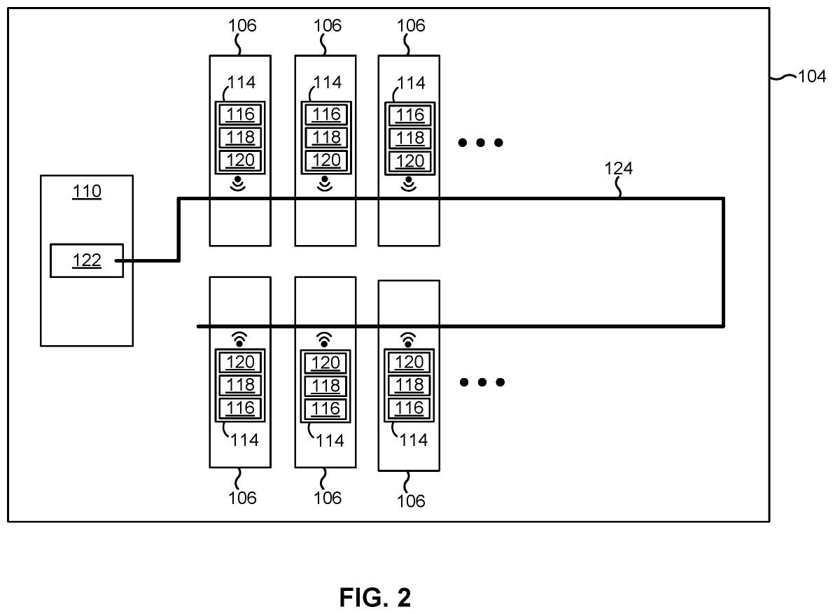

FIG. 2 is a diagram of an example battery module 104. As shown, the battery module 104 may include a plurality of chip-on-cell devices 114 (which can also be referred to as “cell monitoring devices”) connected (e.g., mounted) to respective battery cells 106. A chip-on-cell device 114 may be electrically connected to a battery cell 106, to thereby draw power from the battery cell 106. A chip-on-cell device 114 may include one or more sensors 116 configured to detect electrical characteristics (e.g., a voltage, a current, or the like) of a particular battery cell 106. The chip-on-cell device 114 may include a controller 118 (e.g., including one or more memories and/or one or more processors, in a similar manner as described in FIG. 1) configured to control operations of the chip-on-cell device 114.

The chip-on-cell device 114 may include a wireless transmitter 120 (e.g., one or more wireless transmitters 120) to wirelessly communicate with the module controller 110. The wireless transmitter 120 may be capable of wireless transmission only, or capable of wireless transmission and reception. The wireless transmitter 120 may be configured for short-range wireless communication, and may be referred to herein as a “short-range wireless transmitter 120” or a “first wireless transmitter 120” to differentiate it from other wireless transmitters described herein. The short-range wireless transmitter 120 may include an antenna (not shown) for wireless communication. The short-range wireless transmitter 120 may be a component of the controller 118, or may be a separate component from the controller 118.

Components of the chip-on-cell device 114 (e.g., the sensor(s) 116, the controller 118, and/or the short-range wireless transmitter 120) may be implemented in one or more integrated circuit (IC) chips, such as field programmable gate array (FPGA) chips and/or application specific integrated circuit (ASIC) chips, among other examples. The chip-on-cell device 114 may include a substrate, such as a circuit board (e.g., a printed circuit board), and the components of the chip-on-cell device 114 may be mounted on the substrate or otherwise electrically connected to the substrate.

The module controller 110 may include a wireless receiver 122 (e.g., one or more wireless receivers 122) to wirelessly communicate with the chip-on-cell devices 114. The wireless receiver 122 may be capable of wireless reception only, or capable of wireless transmission and reception. The wireless receiver 122 may be configured for short-range wireless communication, and may be referred to herein as a “short-range wireless receiver 122” or a “first wireless receiver 122” to differentiate it from other wireless receivers described herein.

The short-range wireless receiver 122 may include an antenna 124 for wireless communication. The antenna 124 may be a bus antenna as shown. For example, the antenna 124 may be configured in a path that passes by each of the chip-on-cell devices 114 (e.g., each of the short-range wireless transmitters 120), thereby facilitating wireless communication between the module controller 110 and each of the chip-on-cell devices 114. In some implementations, the module controller 110 and cell monitoring devices for the battery cells 106 may wirelessly communicate using a different system and/or configuration from that described above.

As indicated above, FIG. 2 is provided as an example. Other examples may differ from what is described with regard to FIG. 2.

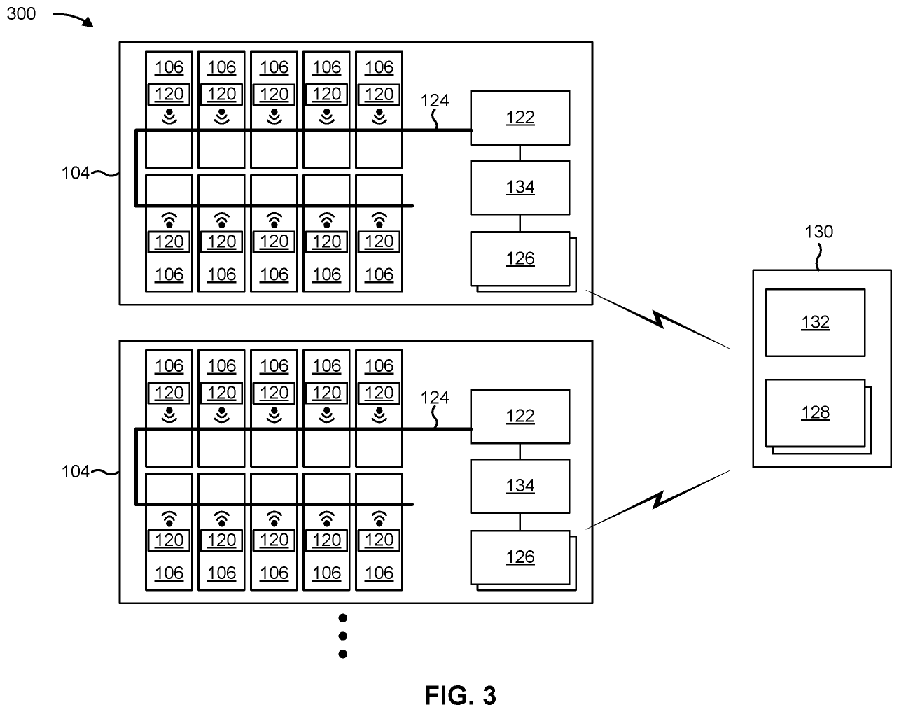

FIG. 3 is a diagram of an example communication system 300. The communication system 300 may enable wireless communication from a battery cell level to a module level, and enable wireless communication from a module level to a pack level, thereby achieving end-to-end wireless communication of the battery pack 100. At a battery module 104, the communication system 300 may include the chip-on-cell devices 114 (e.g., the short-range wireless transmitters 120), the short-range wireless receiver 122, and a wireless transmitter 126 (or multiple wireless transmitters 126 can be used for redundancy). The wireless transmitter 126 may be capable of wireless transmission only, or capable of wireless transmission and reception. The wireless transmitter 126 may be configured for long-range wireless communication, and may be referred to herein as a “long-range wireless transmitter 126” or a “second wireless transmitter 126” to differentiate it from other wireless transmitters described herein.

Additionally, the communication system 300 may include a wireless receiver 128 (or multiple wireless receivers 128 can be used for redundancy) of a BMS 130 of the battery pack 100. The wireless receiver 128 may be capable of wireless reception only, or capable of wireless transmission and reception. The wireless receiver 128 may be configured for long-range wireless communication, and may be referred to herein as a “long-range wireless receiver 128” or a “second wireless receiver 128” to differentiate it from other wireless receivers described herein. The BMS 130 may further include a controller 132 (also referred to as a “BMS controller”), which may correspond to the battery pack controller 108. The long-range wireless receiver 128 may be a component of the controller 132, or may be a separate component from the controller 132.

The chip-on-cell devices 114 may monitor and collect measurements relating to the battery cells 106 (e.g., each chip-on-cell device 114 may monitor and collect measurements relating to a respective battery cell 106). The short-range wireless receiver 122 may receive (e.g., in a first signal or communication) data relating to a battery cell 106 from a chip-on-cell device 114 (e.g., from the short-range wireless transmitter 120 of the chip-on-cell device 114) using a first wireless communication technology (e.g., a first wireless communication protocol). For example, the first wireless communication technology may be a short-range wireless communication technology. In some implementations, “short-range wireless communication” may refer to wireless communication that has a maximum range of 10 millimeters. As an example, the first wireless communication technology may be near-field communication (NFC) or Bluetooth Low Energy (BLE), among other examples. The data received by the short-range wireless receiver 122 may indicate one or more electrical properties of the battery cell 106 (e.g., a voltage, a resistance, an impedance, or the like) and/or a temperature of the battery cell 106, among other examples. The data received by the short-range wireless receiver 122 may be in a first format, which may be a format that cannot be used (e.g., understood) by the controller 132.

The short-range wireless receiver 122 may transfer, and the long-range wireless transmitter 126 may obtain, the data. The data may be transferred from the short-range wireless receiver 122 (e.g., via the module controller 110) to the long-range wireless transmitter 126 via a wired connection. In some implementations, the data may be transferred from the short-range wireless receiver 122 to the long-range wireless transmitter 126 via a processor 134 (e.g., a microprocessor). The processor 134 may have a first wired connection (e.g., a serial interface connection, such as a Serial Peripheral Interface (SPI) connection) to the short-range wireless receiver 122 and a second wired connection (e.g., a serial interface connection, such as a SPI connection) to the long-range wireless transmitter 126 (e.g., the processor 134 bridges the short-range wireless receiver 122 to the long-range wireless transmitter 126).

The processor 134 may process, transform, convert, and/or reformat the data received from the short-range wireless receiver 122 prior to transferring the data to the long-range wireless transmitter 126. For example, the processor 134 may convert the data from the first format (in which the data was received by the short-range wireless receiver 122) to a second format. The second format may be a format that is used by the long-range wireless transmitter 126 and/or a format used (e.g., understood) by the controller 132. In some implementations, the short-range wireless receiver 122 and/or the processor 134 may decode the data according to a first modulation and/or coding scheme, and the processor 134 and/or the long-range wireless transmitter 126 may encode the data according to a second modulation and/or coding scheme.

The long-range wireless transmitter 126 may transmit, and the long-range wireless receiver 128 may receive (e.g., in a second signal or communication), the data using a second wireless communication technology (e.g., a second wireless communication protocol). For example, the second wireless communication technology may be a long-range wireless communication technology. The long-range wireless communication technology has a longer maximum range than a maximum range of the short-range wireless communication technology. In some implementations, “long-range wireless communication” or “far field wireless communication” may refer to wireless communication that has a maximum range greater than 0.5 meters. As an example, the second wireless communication technology may be a wireless local area network (WLAN) technology, Wi-Fi, or a cellular technology, among other examples. The data received by the long-range wireless receiver 128 may be in the second format.

The long-range wireless receiver 128 may communicate the data to the controller 132. For example, the long-range wireless receiver 128 may transfer, and the controller 132 may obtain, the data. In some implementations, the long-range wireless receiver 128 and/or the controller 132 may decode the data according to the second modulation and/or coding scheme. In some implementations, the data may be communicated (e.g., transferred) from the long-range wireless receiver 128 to the controller 132 via a transceiver of the BMS 130. The transceiver may be a component of the controller 132, or a separate component from the controller 132. Communication between the long-range wireless receiver 128 and the transceiver may be by a wired connection or a wireless connection. The controller 132 may use the data to determine characteristics of the battery cell 106, such as an SOC, an SOH, or the like. In this way, the data may be communicated from the chip-on-cell device 114, that collected the data, to the controller 132 in a wireless manner.

As indicated above, FIG. 3 is provided as an example. Other examples may differ from what is described with regard to FIG. 3.

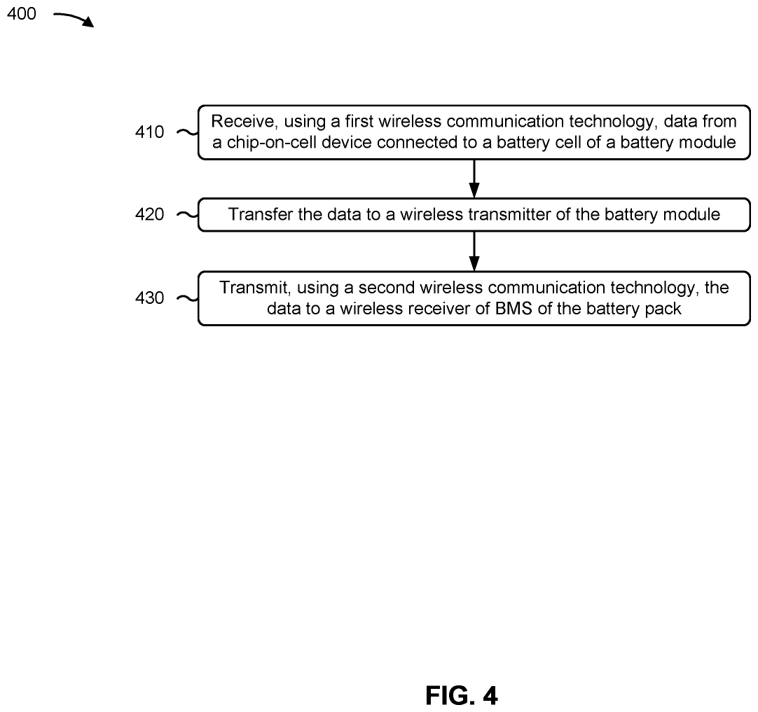

FIG. 4 is a flowchart of an example process 400 associated with hybrid wireless communication for a BMS. One or more process blocks of FIG. 4 may be performed by components of a battery pack (e.g., battery pack 100).

As shown in FIG. 4, process 400 may include receiving, using a first wireless communication technology, data from a first wireless transmitter of a chip-on-cell device connected to a battery cell of the battery module (block 410). For example, a first wireless receiver (e.g., short-range wireless receiver 122) of the battery pack may receive the data from the first wireless transmitter of the chip-on-cell device, as described above. The data may indicate one or more properties of the battery cell detected by the chip-on-cell device (e.g., electrical properties of the battery cell and/or a temperature of the battery cell).

As further shown in FIG. 4, process 400 may include transferring the data to a second wireless transmitter (e.g., long-range wireless transmitter 126) of the battery module (block 420). For example, the first wireless receiver of the battery pack may transfer the data (e.g., using processor 134), as described above. Transferring the data may include transferring the data from the first wireless receiver to the second wireless transmitter via a processor (e.g., processor 134). Process 400 may include converting (e.g., using processor 134) the data from a first format to a second format.

As further shown in FIG. 4, process 400 may include transmitting, using a second wireless communication technology, the data to a second wireless receiver (e.g., long-range wireless receiver 128) of a BMS of the battery pack (block 430). For example, the second wireless transmitter (e.g., long-range wireless transmitter 126) of the battery pack may transmit the data, as described above. The first wireless communication technology may be a short-range wireless communication technology, and the second wireless communication technology may be a long-range wireless communication technology. For example, the first wireless communication technology may be NFC, and the second wireless communication technology may be a WLAN technology. Process 400 may include communicating the data from the second wireless receiver to a transceiver of the BMS.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

### INDUSTRIAL APPLICABILITY

The communication system described herein may be used with any battery pack, such as a battery pack that uses a modular battery cell configuration. For example, the battery pack may be a high-voltage battery pack (e.g., at least 500 volts or at least 1000 volts) of the type used to power an electric vehicle or an electric work machine. In the modular configuration, the battery pack may include multiple battery modules, and each module may include multiple battery cells. In some cases, a battery module of a battery pack may employ a cell monitoring unit that has wired connections to individual battery cells, and the cell monitoring unit of each battery module may have a wired connection to a main BMS controller of the battery pack. These numerous wire connections increase cost and complexity. Moreover, wires are susceptible to electrical defects, wire abrasion, improper installation, and/or disconnection (e.g., due to vibration), among other examples, and therefore are associated with poor reliability.

The communication system described herein is useful for enabling end-to-end wireless communication for a battery pack. In particular, the communication system employs a hybrid wireless communication scheme that uses short-range wireless communication within a battery module and long-range wireless communication from battery modules up to a pack level (e.g., to a main BMS controller). Combining short-range wireless communication and long-range wireless communication allows wire connections to be eliminated from the battery pack, both between cell monitoring devices (e.g., chip-on-cell devices) of individual battery cells and a module-level controller, and between the module-level controller and a pack-level controller of a BMS of the battery pack. In this way, the communication system reduces a cost and complexity of the battery pack and achieves highly-reliable communication within the battery pack. Furthermore, eliminating a physical connection between a high-voltage path of a battery and a low-voltage control network of a BMS also eliminates a need for high-voltage isolation on the BMS hardware that interfaces with the battery, thereby further reducing a cost and complexity of the battery pack.

What is claimed is:

1. A method, comprising:
receiving, by a first wireless receiver of a battery module of a battery pack and using a first wireless communication technology, data from a first wireless transmitter of a chip-on-cell device connected to a battery cell of the battery module,
the data indicating one or more properties of the battery cell detected by the chip-on-cell device;
transferring, by the first wireless receiver, the data to a second wireless transmitter of the battery module; and
transmitting, by the second wireless transmitter and using a second wireless communication technology, the data to a second wireless receiver of a battery management system (BMS) of the battery pack.

2. The method of claim 1, wherein the first wireless communication technology is a short-range wireless communication technology, and the second wireless communication technology is a long-range wireless communication technology.

3. The method of claim 1, wherein the first wireless communication technology is near-field communication, and the second wireless communication technology is a wireless local area network (WLAN) technology.

4. The method of claim 1, wherein transferring the data comprises:
transferring the data from the first wireless receiver to the second wireless transmitter via a processor.

5. The method of claim 4, wherein transferring the data from the first wireless receiver to the second wireless transmitter via the processor comprises:
converting, by the processor, the data from a first format to a second format.

6. The method of claim 1, further comprising:
communicating the data from the second wireless receiver to a transceiver of the BMS.

7. The method of claim 1, wherein the one or more properties of the battery cell include at least one of:
one or more electrical properties of the battery cell, or
a temperature of the battery cell.

8. A battery pack, comprising:
a battery module, comprising:
a plurality of battery cells;
a plurality of chip-on-cell devices connected to respective battery cells of the plurality of battery cells;
a first wireless receiver configured to receive data from a first wireless transmitter of a chip-on-cell device, of the plurality of chip-on-cell devices, using a first wireless communication technology; and
a second wireless transmitter configured to obtain the data from the first wireless receiver via a wired connection; and
a battery management system (BMS), comprising:
a second wireless receiver configured to receive the data from the second wireless transmitter using a second wireless communication technology.

9. The battery pack of claim 8, wherein the second wireless communication technology has a longer maximum range than a maximum range of the first wireless communication technology.

10. The battery pack of claim 8, wherein the first wireless receiver comprises an antenna that is configured in a path that passes by the plurality of chip-on-cell devices.

11. The battery pack of claim 8, wherein the chip-on-cell device comprises:
one or more sensors; and
the first wireless transmitter.

12. The battery pack of claim 8, wherein the BMS further comprises a controller, and wherein the second wireless receiver is a component of the controller.

13. The battery pack of claim 8, wherein the BMS further comprises a controller comprising a transceiver, and
wherein the second wireless receiver is further configured to communicate the data to the transceiver.

14. A communication system for a battery module, comprising:
a plurality of chip-on-cell devices connected to respective battery cells of the battery module;
a first wireless receiver configured to receive data from a first wireless transmitter of a chip-on-cell device, of the plurality of chip-on-cell devices, using a first wireless communication technology; and
a second wireless transmitter configured to transmit the data to a second wireless receiver using a second wireless communication technology.

15. The communication system of claim 14, wherein the second wireless communication technology has a longer maximum range than a maximum range of the first wireless communication technology.

16. The communication system of claim 14, wherein the first wireless receiver comprises an antenna that is configured in a path that passes by the plurality of chip-on-cell devices.

17. The communication system of claim 14, wherein the chip-on-cell device comprises:
one or more sensors; and
the first wireless transmitter.

18. The communication system of claim 14, wherein the data indicates one or more properties of the battery cell detected by the chip-on-cell device.

19. The communication system of claim 14, further comprising:
a processor having a first wired connection to the first wireless receiver and a second wired connection to the second wireless transmitter.

20. The communication system of claim 19, wherein the second wireless transmitter is further configured to obtain the data from the first wireless receiver via the processor.
